(19) United States
(12) Patent Application Publication
(10) Pub. No.: US 2024/0258154 A1
(43) Pub. Date: Aug. 1, 2024

(54) METHOD, ASSEMBLY AND SYSTEM FOR FILM DEPOSITION AND CONTROL

(71) Applicant: ASM IP Holding B.V., Almere (NL)

(72) Inventors: Jereld Lee Winkler, Gilbert, AZ (US); Eric Christopher Stevens, Tempe, AZ (US); Amit Mishra, Tempe, AZ (US); Chad Russell Lunceford, Phoenix, AZ (US); Paul Ma, Scottsdale, AZ (US)

(21) Appl. No.: 18/425,107

(22) Filed: Jan. 29, 2024

Related U.S. Application Data
(60) Provisional application No. 63/442,662, filed on Feb. 1, 2023.

(51) Int. Cl. H01L 21/687; C23C 16/44; C23C 16/455; C23C 16/458; C23C 16/52; H01L 21/3205

(52) U.S. Cl. CPC H01L 21/68735; C23C 16/4412; C23C 16/45527; C23C 16/45544; C23C 16/4585; C23C 16/52; H01L 21/32051; H01L 21/68757; H01L 21/68764

(57) ABSTRACT

Methods, systems, and assemblies suitable for gas-phase processes are disclosed. An exemplary assembly includes a susceptor plate and a susceptor attachment. The susceptor attachment can comprise a ramp region and a conductance control region above and exterior to the ramp region. Methods, systems, and assemblies can be used to obtain desired (e.g., composition and/or thickness) profiles of material on a substrate surface.

### CROSS-REFERENCE TO RELATED APPLICATIONS

This application is a nonprovisional of, and claims priority to and the benefit of, U.S. Provisional Patent Application No. 63/442,662, filed Feb. 1, 2023 and entitled “METHOD, ASSEMBLY AND SYSTEM FOR FILM DEPOSITION AND CONTROL,” which is hereby incorporated by reference herein.

### FIELD OF INVENTION

The present disclosure generally relates to methods and systems used in the formation of electronic devices. More particularly, the disclosure relates to methods and systems suitable for depositing and forming films during substrate processing.

### BACKGROUND OF THE DISCLOSURE

Gas-phase reactors, such as chemical vapor deposition (CVD) reactors and the like, can be used for a variety of applications, including depositing materials to form films on substrates. For example, gas-phase reactors can be used to deposit metal layers on a substrate to form devices, such as semiconductor devices, flat panel display devices, photovoltaic devices, microelectromechanical systems (MEMS), and the like.

A typical reactor system includes a reactor including a reaction chamber, one or more precursor and/or reactant gas sources fluidly coupled to the reaction chamber, one or more carrier and/or third gas sources fluidly coupled to the reaction chamber, a gas injection system to deliver gases (e.g., precursor/reactant gas(es) and/or carrier/purge gas(es)) to the reaction chamber, a susceptor to retain and heat a substrate, and an exhaust source fluidly coupled to the reaction chamber.

During deposition, such as CVD, atomic layer deposition (ALD) and CVD/ALD hybrid, it is often desirable to control film properties, such as film thickness non-uniformity of a thin deposition film. While some techniques have been developed to deposit films on substrates, such methods may result in a film with undesirably high levels of thickness non-uniformity and film properties, such as resistivity. With typical methods and systems, such control may be difficult. Accordingly, improved methods and systems are desired.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to improved methods and systems suitable for depositing material on a surface of a substrate and/or other processes. While the ways in which various embodiments of the present disclosure address drawbacks of prior systems and methods are discussed in more detail below, in general, various embodiments of the disclosure provide methods and systems that can be used to, for example, deposit thin films with reduced and/or desired thickness non-uniformity. For example, exemplary methods can be used to more evenly deposit a film on a substrate such that the center and far edges of the film are more uniform. Examples of the disclosure can provide improved uniformity of film thickness, resistivity, composition, and/or the like.

As described in more detail below, in accordance with example of the disclosure, film deposition utilizing a susceptor assembly comprising a susceptor attachment is disclosed. Such film deposition can provide for more pressure control or facilitate obtaining a desired flow profile for a process (e.g. deposition) by rapidly changing the reaction chamber pressure during different stages of the process. Such pressure regulation can further provide significant advantages in reducing non-uniformity of films deposited and/or lower resistivity of the film.

Examples of the disclosure are conveniently described in connection with formation of metal films, such as molybdenum films, or other grown or deposited layers. However, unless noted otherwise, examples of the disclosure are not so limited.

In accordance with additional embodiments of the disclosure, a susceptor assembly is provided. An exemplary susceptor assembly comprises a susceptor plate and a susceptor attachment. An exemplary susceptor plate comprises a susceptor plate first surface. An exemplary susceptor attachment comprises, a susceptor attachment first surface, the susceptor attachment first surface comprising a ramp region and a conductance control region above and exterior of the ramp region, and a susceptor attachment second surface adjacent the susceptor plate first surface.

In accordance with examples of additional embodiments, the susceptor plate comprises at least one of aluminum, nickel alloy, or ceramic. In accordance with examples of additional embodiments, the susceptor assembly comprises an elevator coupled to the susceptor plate, wherein the elevator is configured to raise and lower the susceptor plate. In accordance with examples of additional embodiments, a controller is in electronic communication with the elevator and is configured to control the raising and lowering of the elevator. In various embodiments, the susceptor attachment is a susceptor cap. In various embodiments, the susceptor attachment is a susceptor ring.

In accordance with additional embodiments of the disclosure, a reactor system is provided. The reactor system includes a reaction chamber comprising an upper region and a lower region, a gas distribution device with a gas distribution device first surface disposed within the upper region and a susceptor assembly as described above and elsewhere herein. In accordance with examples of additional embodiments, a controller can be in electronic communication with the elevator to control the raising and lowering of the susceptor plate. In accordance with additional embodiments of the disclosure, a variable gap can be formed between the gas distribution device first surface and the susceptor cap surface. In accordance with further exemplary embodiments, the controller can operate a low conductance mode, wherein the controller is configured to control or maintain the variable gap between about 0.2 millimeters to about 1.5 millimeters. In accordance with further exemplary embodiments, the controller can operate a high conductance mode, wherein the controller is configured to control or maintain the variable gap between about 3.5 millimeters to about 5.5 millimeters.

In accordance with additional embodiments of the disclosure, another reactor system is provided. The reactor system includes the components of the reactor system as described above and a chamber sealing assembly. In accordance with additional embodiments of the disclosure, the chamber sealing assembly can comprise a sealing ring comprising a sealing ring first surface, a member coupled to the sealing ring first surface, a flange coupled to the member, and a spring coupled to the flange. In further exemplary embodiments, the spring can be coupled to the flange and a reaction chamber flange disposed between the upper region and the lower region.

In accordance with additional embodiments of the disclosure, a method is provided. An exemplary method includes providing a substrate within a reaction chamber of a reactor system, wherein the reactor system comprises an upper region and a lower region, a gas distribution device disposed within the upper region and a susceptor assembly, such as the susceptor assembly as described above or elsewhere herein. In accordance with examples of embodiments, the upper region can comprise a reaction space.

In accordance with examples of embodiments, the method can further comprise manipulating, using the susceptor assembly, a conductance of an exhaust path of the reaction space by moving the conductance control region of the susceptor assembly relative to the gas distribution device first surface. In accordance with examples of embodiments, the step of manipulating the conductance comprises raising the susceptor plate, with the elevator, so that a variable gap between the gas distribution device first surface and the conductance control region of the susceptor attachment first surface is between about 0.2 millimeters to about 1.5 millimeters. In accordance with examples of embodiments, the step of manipulating the conductance comprises lowering the susceptor plate, with the elevator, so that a variable gap between the gas distribution device first surface and the conductance control region of the susceptor attachment first surface is between about 3.5 millimeters to about 5.5 millimeters.

In accordance with examples of embodiments, the method can further comprise one or more deposition cycles. In accordance with further examples of embodiments, the one or more deposition cycles can comprise pulsing a first precursor into the reaction chamber, wherein the first precursor is pulsed into the reaction chamber at a first pressure and a first flow rate, purging a first purge gas into the reaction chamber, and pulsing a reactant into the reaction chamber, wherein the reactant is pulsed into the reaction chamber at a second pressure and a second flow rate. In yet further embodiments, the method can include purging the lower region of the reaction chamber.

In accordance with additional embodiments of the disclosure, another method is provided. An exemplary method includes providing a substrate within a reaction chamber of a reactor system. The reactor system can be as described above or elsewhere herein. In accordance with examples of embodiments, the method can further comprise depositing a layer on the substrate, wherein depositing the layer on the substrate can comprises one or more deposition cycles. In accordance with examples of embodiments, the one or more deposition cycles can comprise pulsing a first precursor into the reaction chamber, wherein the first precursor is pulsed into the reaction chamber at a first pressure and a first flow rate, purging the reaction chamber using a first purge gas, manipulating, using a susceptor assembly, a conductance of an exhaust path of a reaction space, and pulsing a reactant into the reaction chamber, wherein the reactant is pulsed into the reaction chamber at a second pressure and a second flow rate, wherein the first pressure is different than the second pressure. The one or more deposition cycles can be repeated until the layer has a thickness between about 20 Angstroms and about 300 Angstroms.

In accordance with examples of embodiments, the first pressure can be between about 1 torr and about 20 torr and the second pressure can be between about 50 torr and 200 torr. In yet further examples of embodiments, the first precursor can comprise molybdenum and the reactant can comprise a reducing agent. In accordance with yet further embodiments, the first flow rate can be between about 50 standard cubic centimeters per minute and about 2000 standard cubic centimeters per minute, and the second flow rate can be between about 1 standard liter per minute and about 40 standard liters per minute. In various embodiments, the second flow rate is between about 1 times greater to about 10 times greater than the first flow rate. In various embodiments, a ratio of the second pressure to the first pressure is at least 10:1.

In accordance with additional embodiments of the disclosure, yet another method is provided. An exemplary method includes providing a substrate within a reaction chamber of a reactor system. The reactor system can be as described above or elsewhere herein. In accordance with examples of embodiments, the method can further comprise depositing a layer on the substrate. In accordance with examples of embodiments, the depositing the layer on the substrate can comprise flowing a reactant into the reaction chamber, wherein the reactant continuously flows into the reaction chamber, manipulating a gas flow conductance between a gas distribution device and an exhaust duct, and pulsing a first precursor into the reaction chamber, wherein the first precursor is pulsed into the reaction chamber. In accordance with examples of embodiments, the process conditions can be the same as described above or elsewhere herein. In accordance with examples of embodiments, the gas flow conductance is manipulated by varying a variable gap between a gas distribution device first surface and a conductance control region of a susceptor attachment.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrate a top perspective view of a susceptor assembly in accordance with exemplary embodiments of the disclosure.

FIG. 2 illustrates a cross sectional view of a susceptor assembly in accordance with exemplary embodiments of the disclosure.

FIG. 3 illustrates a cross sectional view of a reactor system in accordance with exemplary embodiments of the disclosure.

FIG. 4 illustrates a cross sectional view of a reactor system in accordance with exemplary embodiments of the disclosure.

FIG. 5 illustrates a cross sectional view of a susceptor assembly in accordance with exemplary embodiments of the disclosure.

FIG. 6 illustrates a cross sectional view of a reactor system in accordance with exemplary embodiments of the disclosure.

FIG. 7 illustrates a cross sectional view of a reactor system in accordance with exemplary embodiments of the disclosure.

FIG. 8 illustrates a method in accordance with exemplary embodiments of the disclosure.

FIG. 9 illustrates a method in accordance with exemplary embodiments of the disclosure.

FIG. 10 illustrates a method in accordance with exemplary embodiments of the disclosure.

It will be appreciated that elements in the figures are illustrated for simplicity and clarity and have not necessarily been drawn to scale. For example, the dimensions of some of the elements in the figures can be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods, assemblies and systems suitable for use in reactor systems. Such methods, assemblies, and systems can be used to form layers and/or for other processes, such as etch or clean, during formation of devices. By way of examples, the methods, assemblies, and systems can be used to form layers with desired composition and/or thickness profiles, with improved control of such properties from the center to the edge of the substrate.

As used herein, the terms “precursor” and/or “reactant” can refer to one or more gases/vapors that take part in a chemical reaction or from which a gas-phase substance that takes part in a reaction is derived. The terms precursor and reactant can be used interchangeably. The chemical reaction can take place in the gas phase and/or between a gas phase and a surface (e.g., of a substrate or reaction chamber) and/or a species on a surface (e.g., of a substrate or a reaction chamber).

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate.

As used herein, the term “film” and/or “layer” can refer to any continuous or non-continuous structure and material, such as material deposited by the methods disclosed herein. For example, a film and/or layer can include two-dimensional materials, three-dimensional materials, nanoparticles, partial or full molecular layers or partial or full atomic layers or clusters of atoms and/or molecules. A film or layer may comprise, or may consist at least partially of, a plurality of dispersed atoms on a surface of a substrate and/or may be or may become embedded in a substrate. A film or layer may comprise material or a layer with pinholes and/or isolated islands. A film or layer may be at least partially continuous. In some cases, a film can include two or more layers.

The term “deposition process” as used herein can refer to the introduction of precursors (and/or reactants) into a reaction chamber to deposit or form a layer over a substrate. This can include CVD, ALD and CVD/ALD hybrid deposition.

In this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

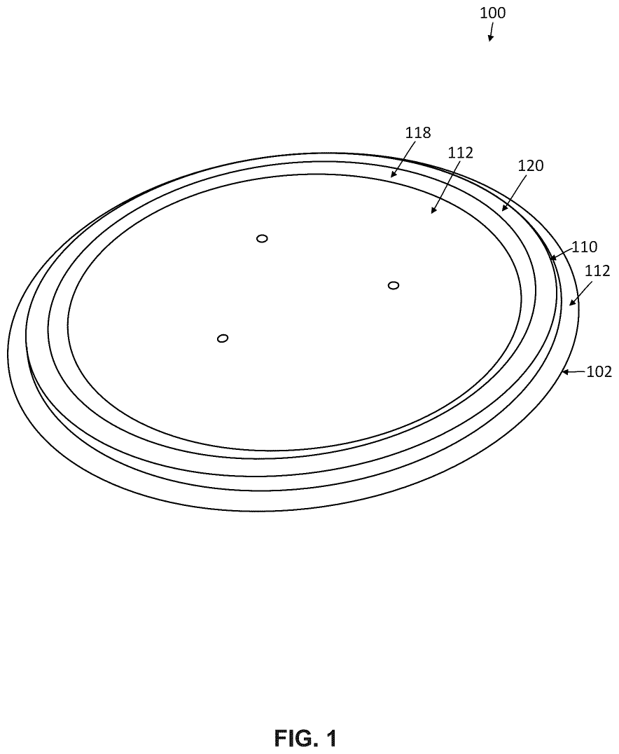

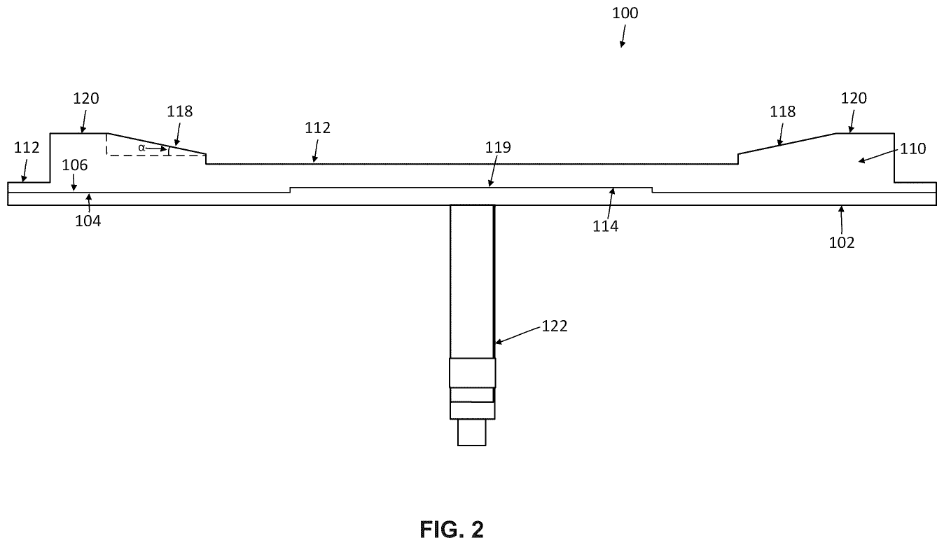

Turning now to the figures, FIGS. 1-2 illustrate different views of an exemplary susceptor assembly 100 according to embodiments of the present disclosure. The susceptor assembly 100 comprises a susceptor plate 102 comprising a susceptor plate first surface 104 and a susceptor attachment 110. The susceptor plate 102 is be formed of, for example graphite, aluminum, nickel alloy or thermally conductive ceramic. In the illustrated example, the susceptor attachment 110 is a susceptor cap. Susceptor attachment 110 comprises a susceptor attachment first surface 112 and a susceptor attachment second surface 106. The susceptor attachment second surface 106 comprises a cavity 119. The susceptor attachment 110 can be coupled to the susceptor plate 102 by coupling the cavity 119 of the susceptor attachment 110 to a susceptor notch 114 of the susceptor plate 102. The susceptor attachment first surface 112 comprises a ramp region 118 and a conductance control region 120 above and exterior of the ramp region 118. The ramp region 118 comprises a ramp angle α. The ramp angle α is the angle between the ramp region 118 and the susceptor plate first surface 104. In various embodiments, the ramp angle α can be between about 10 degrees and about 30 degrees or between about 20 degrees and 45 degrees. The susceptor attachment 110 is configured to hold a substrate in the center of the susceptor attachment 110 for use in deposition processes. Additionally, the susceptor assembly 100 comprises an elevator 122, which is a motor system configured to raise and lower the susceptor assembly 100.

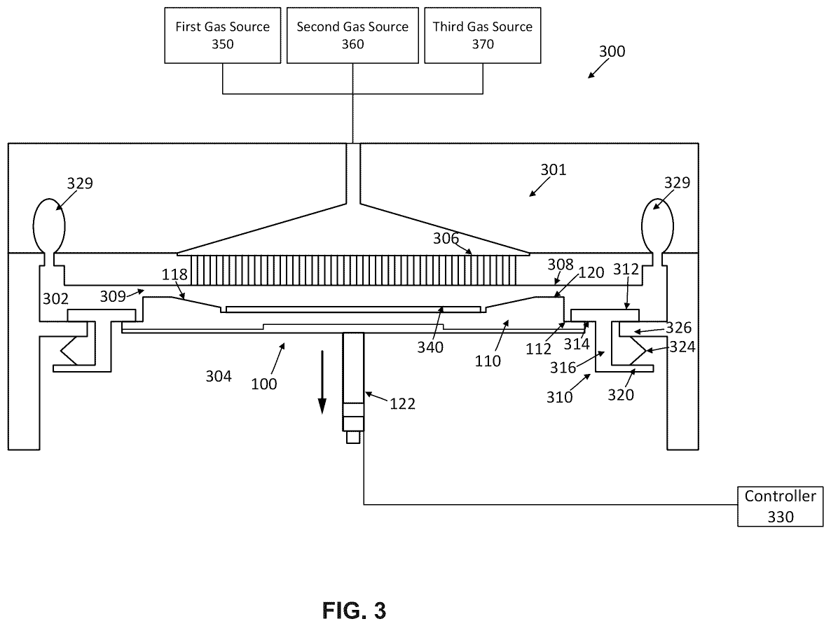

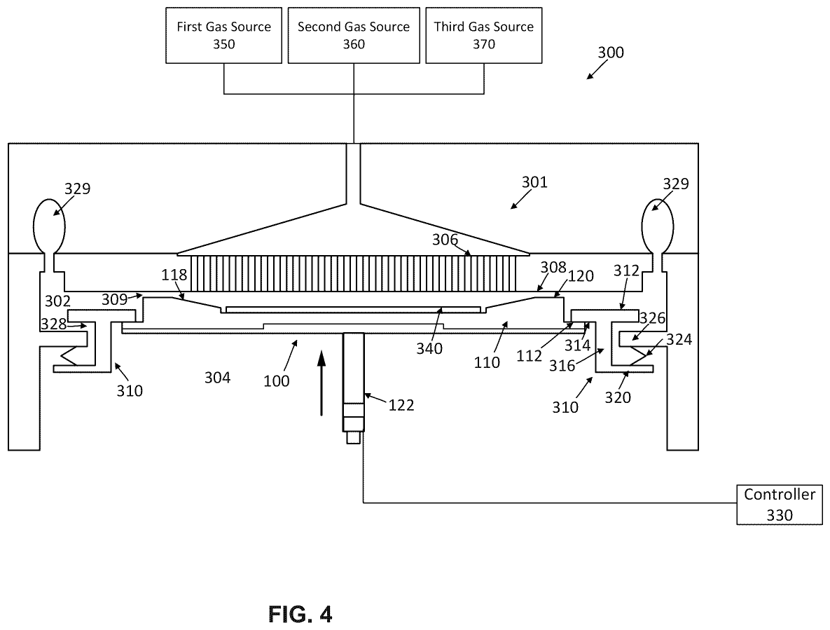

With additional reference to FIG. 3 and FIG. 4, a reactor system 300 is illustrated with different operational modes. Reactor system 300 includes susceptor assembly 100 provided with a substrate 340 within a reaction chamber 301. In various embodiments, the substrate 340 can be placed on the susceptor attachment 110. The reaction chamber 301 comprises an upper region 302 and a lower region 304. A gas distribution device 306 is disposed within the reaction chamber 301 and the gas distribution device 306 is configured to deliver gas to the upper region 302 of the reaction chamber 301 using CVD deposition, ALD deposition, and/or ALD/CVD hybrid deposition.

In various embodiments, a first gas source 350, second gas source 360, and third gas source 370 are in fluid communication with the gas distribution device 306. The first gas source 350 is configured to deliver a first precursor to the gas distribution device 306. The first precursor can be or include, for example, molybdenum (Mo) precursors, for example MoO₂Cl₂, MoCl₅, MoCl₆, or metalorganic molybdenum. The second gas source 360 is configured to deliver a reactant to the gas distribution device 306. The reactant can be or include a reducing agent, for example hydrogen gas (H₂). The third gas source 370 is configured to deliver a purge gas to the gas distribution device 306. The purge gas can be or include an inert gas, for example argon (Ar), nitrogen gas (N₂), or the like. One or more exhaust duct(s) 329 can be disposed within the upper region 302 to assist in removing gas from the reaction chamber 301. In various embodiments, the exhaust duct(s) 329 can be in fluid communication with a dual-throttle valve system to rapidly remove exhaust gases from the reaction chamber 301.

Additionally, gas distribution device 306 comprises a gas distribution device first surface 308. A variable gap 309 is formed between the gas distribution device first surface 308 and the conductance control region 120 of the susceptor attachment 110. The variable gap 309 is configured to exhaust gas from the upper region 302 to the lower region 304 and exhaust ducts 329. A pressure and reaction space volume in the reaction chamber 301 can be controlled by the width of the variable gap 309. When variable gap 309 has a smaller width, the volume of the reaction space and/or an exhaust conductance is decreased and the pressure within the reaction chamber 301 increases during gas deposition. When variable gap 309 has a wider width, the volume of the reaction space and/or the exhaust conductance is increased and the pressure within the reaction chamber 301 decreases during gas deposition.

In some examples, the elevator 122 is coupled to the susceptor assembly 100 and the elevator 122 is configured to raise and lower the susceptor assembly 100 within the upper region 302. A controller 330 is in electric communication with the elevator 122. The controller 330 is configured to control the elevator 122 to raise and lower the susceptor assembly 100. The controller can also be in communication with other systems in the reactor system, including the first gas source 350, the second gas source 360 and the third gas source 370 to control the introduction of gases from those sources to the gas distribution device 306 and into the upper region 302 of the reaction chamber 301.

As illustrated, the controller 330 comprises a low conductance mode (illustrated in FIG. 4) and a high conductance mode (illustrated in FIG. 3). In low conductance mode, the controller 330 controls or maintains a position of the elevator 122 such that the variable gap 309 is between, for example, about 0.2 millimeters and about 1.5 millimeters or between about 0.5 millimeters and about 1 millimeter. The controller 330 can be configured to move and/or maintain the elevator 122 such that the variable gap 309 is between about 0.2 millimeters and about 1.5 millimeters or between about 0.5 millimeters and about 1 millimeter, and thereafter can control the variable gap 309 in such range. In high conductance mode, the controller 330 controls or maintains a position of the elevator 122 such that the variable gap 309 is between, for example, about 3.5 millimeters and about 5.5 millimeters or between about 4 millimeters and about 5 millimeters. The controller 330 can be configured to move and/or maintain the elevator 122 such that the variable gap 309 is between about 3.5 millimeters and about 5.5 millimeters or between about 4 millimeters and about 5 millimeters, and thereafter can control the variable gap 309 in such range.

In exemplary embodiments, reactor system 300 also comprises a chamber sealing assembly 310. Chamber sealing assembly 310 is used to seal the upper region 302 from the lower region 304 when the reactor system 300 is in high conductance mode or provide a more tortuous path therebetween. The chamber sealing assembly 310 comprises a sealing ring 312. The sealing ring 312 comprises a sealing ring first surface 314 which is in contact with the susceptor attachment first surface 112. The sealing ring 312 can be formed of aluminum, nickel alloy, ceramic or quartz. A member 316 is coupled to the sealing ring first surface 314 and a flange 320 is coupled to member 316. A spring 324 is also coupled to the flange 320. In various embodiments, the reaction chamber 301 comprises a reaction chamber flange 326 disposed between the upper region 302 and the lower region 304. In various embodiments, the spring 324 is coupled to the reaction chamber flange 326 and the flange 320.

In exemplary embodiments, when the reactor system 300 switches from high conductance mode to low conductance mode the sealing ring 312 raises along with the susceptor assembly 100 and an exhaust path 328 opens between the sealing ring 312 and the reaction chamber flange 326. The exhaust path 328 allows for exhaust gas from the reaction chamber 301 to be transferred from the upper region 302 to the lower region 304. Additionally, the spring 324 biases the flange 320 opposite of the reaction chamber flange and holds the sealing ring 312 against the susceptor attachment first surface 112. Additionally, the biasing of spring 324 can help with quick position changes and control of the susceptor assembly 100 when transferring between the low conductance mode and the high conductance mode.

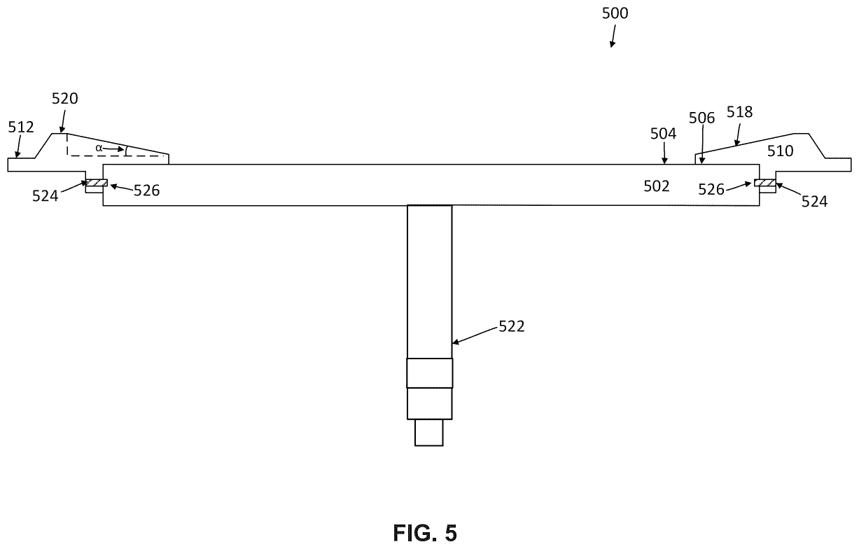

FIG. 5 illustrates an exemplary susceptor assembly 500 according to embodiments of the present disclosure. The susceptor assembly 500 comprises a susceptor plate 502 comprising a susceptor plate first surface 504 and a susceptor attachment 510. The susceptor plate 502 can be formed of, for example graphite, aluminum, nickel alloy or ceramic. In the illustrated example, the susceptor attachment 510 is a susceptor ring. Susceptor attachment 510 comprises a susceptor attachment first surface 512 and a susceptor attachment second surface 506. The susceptor attachment 510 can be coupled to the susceptor plate 502 by coupling the susceptor attachment second surface 506 to the susceptor plate first surface 504. In the illustrated example, one or more connector pins 524 can be used to further couple the susceptor attachment 510 to the susceptor plate 502. The susceptor attachment 510 can comprise the connector pins 524 and the susceptor plate 502 can comprise one or more connector inlets 526 configured to receive the one or more connector pins 524.

The susceptor attachment first surface 512 comprises a ramp region 518 and a conductance control region 520 above and exterior of the ramp region 518. The ramp region 518 can include an incline surface, having a ramp angle α. The ramp angle α is the angle between the ramp region 518 and the susceptor plate first surface 504. In various embodiments, the ramp angle α can be between about 10 degrees and about 30 degrees or between about 20 degrees and 45 degrees. The susceptor attachment 510 is configured to hold a substrate in the center of the susceptor attachment 510 while the substrate is placed on the susceptor plate first surface 504 for use in deposition processes. Additionally, the susceptor assembly 500 can include an elevator 522, which can include a motor system 575 configured to raise and lower the susceptor assembly 500. The motor system 575 can be communicatively coupled to a controller as described herein.

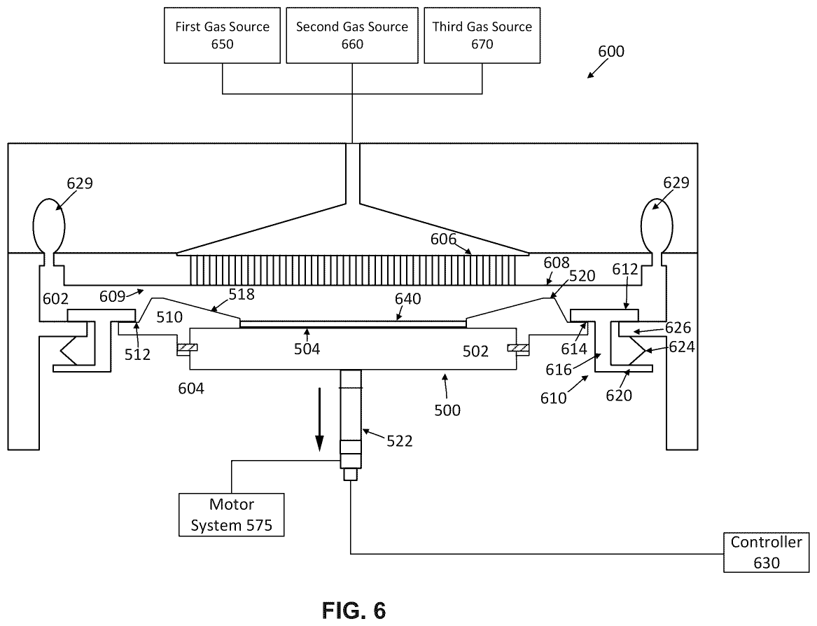

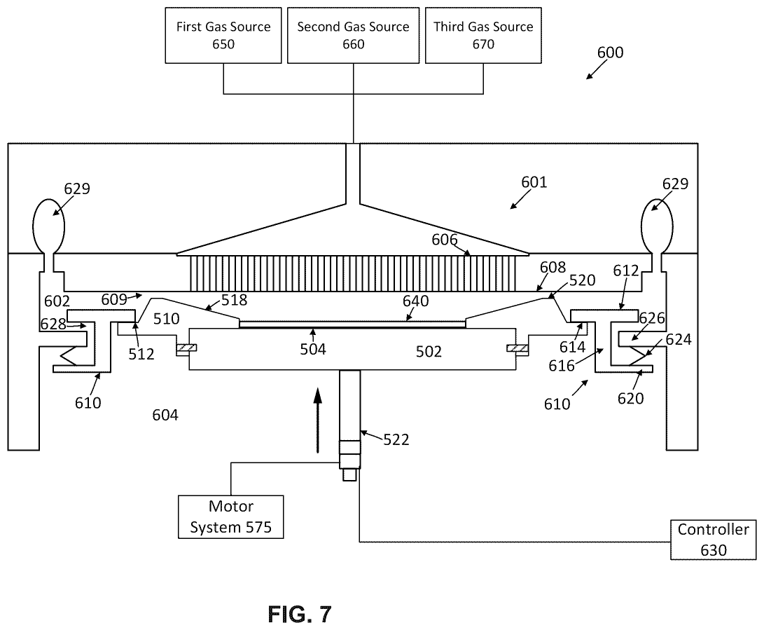

With additional reference to FIG. 6 and FIG. 7, another reactor system 600 is illustrated with different operational modes. Reactor system 600 includes susceptor assembly 500 provided with a substrate 640 within a reaction chamber 601. In various embodiments, the substrate 640 can be placed on the susceptor plate first surface 504. The reaction chamber 601 comprises an upper region 602 and a lower region 604. A gas distribution device 606 is disposed within the reaction chamber 601 and the gas distribution device 606 can be configured to deliver gas to the upper region 602 of the reaction chamber 601 using CVD deposition, ALD deposition, and/or ALD/CVD hybrid deposition.

In various embodiments, a first gas source 650, second gas source 660, and third gas source 670 are in fluid communication with the gas distribution device 606. The first gas source 650 can be configured to deliver a first precursor to the gas distribution device 606. The first precursor can be or include, for example, molybdenum (Mo), for example MoO₂Cl₂, MoCl₅, MoCl₆, or metalorganic molybdenum. The second gas source 660 can be configured to deliver a reactant to the gas distribution device 606. The reactant can be or include a reducing agent, for example hydrogen gas (H₂) or the like. The third gas source 670 is configured to deliver a purge gas to the gas distribution device 606. The purge gas can be or include an inert gas, for example argon (Ar),nitrogen gas (N₂), or the like. Exhaust ducts 629 are disposed within the upper region 602 to assist in removing gas from the reaction chamber 601. In various embodiments, the exhaust duct(s) 629 can be in fluid communication with a dual-throttle valve system to rapidly remove exhaust gases from the reaction chamber 601.

Additionally, gas distribution device 606 comprises a gas distribution device first surface 608. A variable gap 609 is formed between the gas distribution device first surface 608 and the conductance control region 520 of the susceptor attachment 510. The variable gap 609 is configured to exhaust gas from the upper region 602 to the lower region 604 and exhaust ducts 629. The pressure and reaction space volume in the reaction chamber 601 can be controlled by the width of the variable gap 609. When variable gap 609 has a smaller width, the volume of the reaction space is decreased and the pressure within the reaction chamber 601 increases during gas deposition. When variable gap 609 has a wider width, the volume of the reaction space is increased and the pressure within the reaction chamber 601 decreases during gas deposition.

In some examples, the elevator 522 is coupled to the susceptor assembly 500 and the elevator 522 is configured to raise and lower the susceptor assembly 500 within the upper region 602. A controller 630 is in electric communication with the elevator 522. The controller 630 is configured to control the elevator 522 to raise and lower the susceptor assembly 500. The controller can also be in communication with other systems in the reactor system, including the first gas source 650, the second gas source 660 and the third gas source 670 to control the introduction of gases from those sources to the gas distribution device 606 and into the upper region 602 of the reaction chamber 601.

As illustrated, the controller 630 comprises a low conductance mode (illustrated in FIG. 6) and a high conductance mode (illustrated in FIG. 7). In low conductance mode, the controller 630 controls or maintains a position of the elevator 522 such that the variable gap 609 is between, for example, about 0.2 millimeters and about 1.5 millimeters or between about 0.5 millimeters and about 1 millimeter. The controller 630 can be configured to move and/or maintain the elevator 522 such that the variable gap 609 is between about 0.2 millimeters and about 1.5 millimeters or between about 0.5 millimeters and about 1 millimeter, and thereafter can control or maintain the variable gap 609 in such range. In high conductance mode, the controller 630 controls or maintains a position of the elevator 522, such that the variable gap 609 is between, for example, about 3.5 millimeters and about 5.5 millimeters or between about 4 millimeters and about 5 millimeters. The controller 630 can be configured to move and/or maintain the elevator 522, such that the variable gap 609 is between about 3.5 millimeters and about 5.5 millimeters or between about 4 millimeters and about 5 millimeters, and thereafter can control or maintain the variable gap 609 in such range.

In exemplary embodiments, reactor system 600 also comprises a chamber sealing assembly 610. Chamber sealing assembly 610 can be used to seal the upper region 602 from the lower region 604 or provide a more tortuous path therebetween when the reactor system 600 is in high conductance mode. The chamber sealing assembly 610 comprises a sealing ring 612. The sealing ring 612 comprises a sealing ring first surface 614 which is in contact with the susceptor attachment first surface 512. The sealing ring 612 can be formed of aluminum, nickel alloy, ceramic or quartz. A member 616 is coupled to the sealing ring first surface 614 and a flange 620 is coupled to member 616. A spring 624 is also coupled to the flange 620. In various embodiments, the reaction chamber 601 comprises a reaction chamber flange 626 disposed between the upper region 602 and the lower region 604. In various embodiments, the spring 624 is coupled to the reaction chamber flange 626 and the flange 620.

In exemplary embodiments, when the reactor system 600 is in low conductance mode the sealing ring 612 raises along with the susceptor assembly 500 and an exhaust path 628 opens between the sealing ring 612 and the reaction chamber flange 626. The exhaust path 628 allows for exhaust gas from the reaction chamber 601 to be transferred from the upper region 602 to the lower region 604. Additionally, the spring 624 biases the flange 620 opposite of the reaction chamber flange and holds the sealing ring 612 against the susceptor attachment first surface 512. Additionally, the biasing of spring 624 can help with quick position changes and control of the susceptor assembly 500 when transferring between the low conductance mode and the high conductance mode.

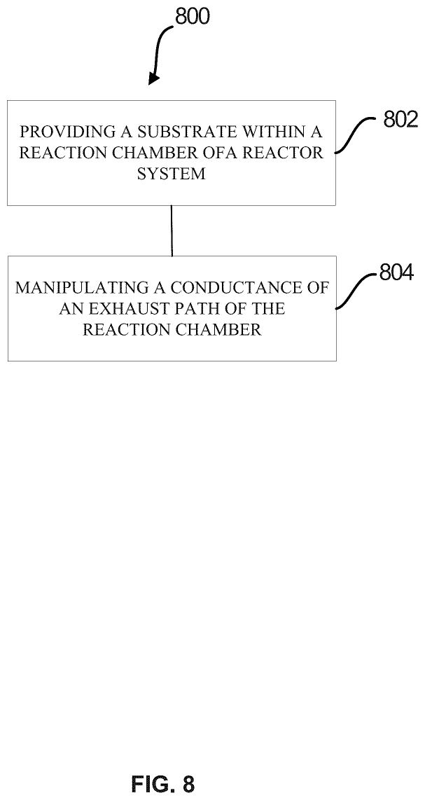

With reference to FIG. 8, a method 800 according to embodiments of the disclosure is illustrated. Method 800 includes a step 802 of providing a substrate (such as substrates 340 and 640) within a reaction chamber (such as reaction chambers 301 and 601) of a reactor system (such as reactor systems 300 and 600) and a step 804, which involves manipulating, using a susceptor assembly (such as susceptor assemblies 100 and 500), a conductance of an exhaust path of the reaction space by moving the conductance control region (such as conductance control regions 120 and 520) of the susceptor assembly relative to a gas distribution device first surface (such as gas distribution device first surfaces 308 and 608).

In various embodiments, step 804 further comprises a low conductance mode wherein the elevator is in electronic communication with a controller (such as controllers 330 and 630), such that the controller can control the elevator to raise and/or maintain the susceptor plate to decrease and/or maintain a variable gap (such as variable gaps 309 and 609) between the conductance control region and the gas distribution device first surface. The variable gap can be decreased to, for example, between about 0.2 millimeters and about 1.5 millimeters or between about 0.5 millimeters and about 1 millimeter.

In various embodiments, step 804 further comprises a high conductance mode, wherein the controller controls the elevator to lower and/or maintain the susceptor plate to increase and/or maintain the variable gap between the conductance control region and the gas distribution device first surface. The variable gap can be increased or maintained to, for example, between about 3.5 millimeters and about 5.5 millimeters or between about 4 millimeters and about 5 millimeters.

The reactor system can be configured to decrease or increase the variable gap between about 50 milliseconds and about 150 milliseconds, or between about 100 milliseconds and about 125 milliseconds. When the reactor system is in high conductance mode the reactor system can rapidly decrease the pressure of the reaction space by increasing the width of the gap and in the low conductance mode it can rapidly increase the pressure of the reaction space. Such operation can be important to the deposition process to decrease and/or increase the pressure rapidly depending on the deposition process.

Additionally, method 800 can involve pulsing a first precursor (such as the first precursor defined above or elsewhere herein) into the reaction chamber at a first pressure and a first flow rate. In various embodiments, the controller can increase the conductance while pulsing the first precursor. In various embodiments, the first pressure can be between about 0.5 torr and about 30 torr, or between about 1 torr and 20 torr. In various embodiments, the first flow rate can be between about 40 standard cubic centimeters per minute (sccm) and about 2100 sccm, or between about 50 sccm and about 2000 sccm. Method 800 can also include purging a first purge gas (such as the first purge gas defined above or elsewhere herein) into the reaction chamber after controlling the elevator in a high conductance mode. The pressure in the reaction chamber during purging of the first purge gas can be between about 0.5 torr and about 30 torr, or between about 1 torr and 20 torr.

Further, method 800 can involve pulsing a reactant (such as the reactant defined above or elsewhere herein) into the reaction chamber at a second pressure and second flow rate. In various embodiments, the second pressure in the reaction chamber can be between about 40 torr and about 250 torr, or between about 50 torr and 200 torr. In various embodiments, the second flow rate of the reactant can be between about 0.8 standard liters per minute (slm) and about 21 slm, or between about 1 slm and about 21 slm.

In various embodiments, the steps for method 800 can be repeated until a layer is formed on the substrate with a thickness between about 15 angstroms and about 300 angstroms or between about 20 angstroms and about 300 angstroms.

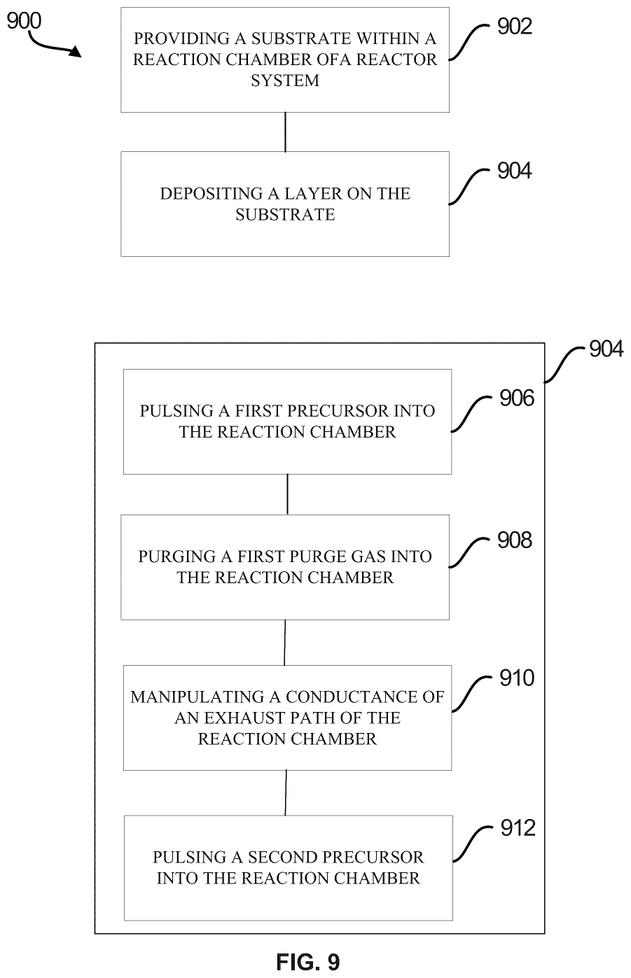

With reference to FIG. 9, a method 900 according to embodiments of the disclosure is illustrated. Method 900 includes a step 902 of providing a substrate (such as substrates 340 and 640) within a reaction chamber (such as reaction chambers 301 and 601) of a reactor system (such as reactor systems 300 and 600).

Method 900 can include a step 904, which involves depositing a layer on the substrate. Method 900 can deposit the layer using ALD. The layer can comprise molybdenum. Step 904 can be repeated by the reactor system until the layer has a thickness between about 15 angstroms and about 300 angstroms or between about 20 angstroms and about 300 angstroms.

Additionally, step 904 of method 900 can include a step 906, which involves pulsing a first precursor (such as the first precursor defined above or elsewhere herein) into the reaction chamber. A first pressure in the reaction chamber during pulsing of the first precursor can be between about 0.5 torr and about 30 torr, or between about 1 torr and 20 torr. It can be important to the deposition process to decrease the pressure rapidly depending on the deposition process. The reactor system can be configured to generate the first pressure in between about 50 milliseconds and about 150 milliseconds, or between about 100 milliseconds and about 125 milliseconds.

In various embodiments, the temperature of the reaction chamber during pulsing of the first precursor can be about 200° C. to about 650° C., or about 300° C. to about 600° C. A first flow rate of the first precursor can be between about 40 standard cubic centimeters per minute (sccm) and about 2100 sccm, or between about 50 sccm and about 2000 sccm.

Further, step 904 of method 900 can include a step 908, which involves purging a first purge gas (such as the first purge gas defined above or elsewhere herein) into the reaction chamber. The pressure in the reaction chamber during purging with the first purge gas is configured to be between about 0.5 torr and about 30 torr, or between about 1 torr and 20 torr. In various embodiments, the temperature of the reaction chamber during purging with the first purge gas can be about 200° ° C. to about 650° C., or about 300° C. to about 600° C.

Additionally, step 904 of method 900 can include a step 910, which involves manipulating, using a susceptor assembly (such as susceptor assemblies 100 and 500), a conductance of an exhaust path of the reaction space by moving the conductance control region (such as conductance control regions 120 and 520) of the susceptor assembly relative to a gas distribution device first surface (such as gas distribution device first surfaces 308 and 608).

In various embodiments, step 910 further comprises a low conductance mode wherein the elevator is in electronic communication with a controller (such as controllers 330 and 630), such that the controller can control the elevator to raise the susceptor plate to decrease a variable gap (such as variable gaps 309 and 609) between the conductance control region and the gas distribution device first surface. The variable gap can be decreased to, for example, between about 0.2 millimeters and about 1.5 millimeters or between about 0.5 millimeters and about 1 millimeter.

Finally, step 904 of method 900 can include a step 912, which involves pulsing a reactant (such as the reactant defined above or elsewhere herein) into the reaction chamber. A second pressure in the reaction chamber during pulsing of the reactant is configured to be between about 40 torr and about 250 torr, or between about 50 torr and 200 torr. It can be important to the deposition process to increase the pressure rapidly depending on the deposition process. The reactor system can be configured to generate the second pressure in between about 50 milliseconds and about 150 milliseconds, or between about 100 milliseconds and about 125 milliseconds.

In various embodiments, the temperature of the reaction chamber during pulsing of the reactant can be about 200° ° C. to about 650° C., or about 300° C. to about 600° C. A second flow rate of the reactant can be between about 0.8 standard liters per minute (slm) and about 21 slm, or between about 1 slm and about 21 slm. In various embodiments, an additional purge, with the similar deposition characteristics as step 908, can be done after step 912.

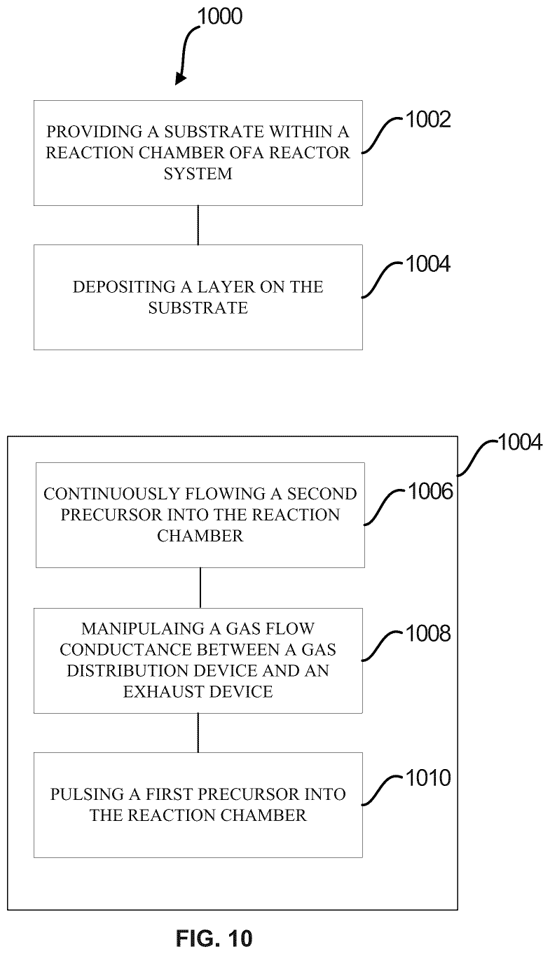

With reference to FIG. 10, a method 1000 according to embodiments of the disclosure is illustrated. Method 1000 includes a step 1002 of providing a substrate (such as substrates 340 and 640) within a reaction chamber (such as reaction chambers 301 and 601) of a reactor system (such as reactor systems 300 and 600). Method 1000 can include a step 704, which involves depositing a layer on the substrate. Method 700 can deposit the layer using CVD. Using CVD for this process can boost nucleation of the layer as it forms. The layer can comprise molybdenum, titanium, tantalum, titanium nitride and/or tantalum nitride. Step 1004 can be repeated by the reactor system until the layer has a thickness between about 15 angstroms and about 300 angstroms or between about 20 angstroms and about 300 angstroms.

Additionally, step 1004 of method 1000 can include a step 1006, which involves continuously flowing a reactant (such as the reactant defined above or elsewhere herein) into the reaction chamber. A second pressure in the reaction chamber during flowing of the reactant is configured to be between about 40 torr and about 250 torr, or between about 50 torr and 200 torr. In various embodiments, the temperature of the reaction chamber during flowing of the reactant can be about 200° ° C. to about 650° ° C., or about 300° ° C. to about 600° C. A second flow rate of the reactant can be between about 0.8 slm and about 21 slm, or between about 1 slm and about 21 slm.

Further, step 1004 of method 1000 can include a step 1008, which involves manipulating, using a susceptor assembly (such as susceptor assemblies 100 and 500), a conductance of an exhaust path of the reaction space by moving the conductance control region (such as conductance control regions 120 and 520) of the susceptor assembly relative to a gas distribution device first surface (such as gas distribution device first surfaces 308 and 608).

In various embodiments, step 1008 further comprises a low conductance mode wherein the elevator is in electronic communication with a controller (such as controllers 330 and 630), such that the controller can control the elevator to raise the susceptor plate to decrease a variable gap (such as variable gaps 309 and 609) between the conductance control region and the gas distribution device first surface. The variable gap can be decreased to, for example, between about 0.2 millimeters and about 1.5 millimeters or between about 0.5 millimeters and about 1 millimeter.

In various embodiments, step 1008 further comprises a high conductance mode wherein the controller controls the elevator to lower the susceptor plate to increase the variable gap between the conductance control region and the gas distribution device first surface. The variable gap can be increased to, for example, between about 3.5 millimeters and about 5.5 millimeters or between about 4 millimeters and about 5 millimeters.

Finally, step 1004 of method 1000 can include a step 1010, which involves pulsing a first precursor (such as the first precursor defined above or elsewhere herein) into the reaction chamber. A first pressure in the reaction chamber during pulsing of the first precursor is configured to be between about 0.5 torr and about 30 torr, or between about 1 torr and 20 torr. The reactor system can be configured to generate the first pressure in between about 50 milliseconds and about 150 milliseconds, or between about 100 milliseconds and about 125 milliseconds.

In various embodiments, the temperature of the reaction chamber during pulsing of the first precursor can be about 200° C. to about 650° C., or about 300° C. to about 600° C. A first flow rate of the first precursor can be between about 40 sccm and about 2100 sccm, or between about 50 sccm and about 2000 sccm. In various embodiments, method 1000 can involve purging the reaction chamber with a first purge gas (such as the first purge gas defined above or elsewhere herein). The pressure in the reaction chamber during purging with the first purge gas is configured to be between about 0.5 torr and about 30 torr, or between about 1 torr and 20 torr. In various embodiments, the temperature of the reaction chamber during purging with the first purge gas can be about 200° C. to about 650° C., or about 300° C. to about 600° C.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A susceptor assembly, comprising:
a susceptor plate comprising a susceptor plate first surface; and
a susceptor attachment comprising:
a susceptor attachment first surface, the susceptor attachment first surface comprising a ramp region and a conductance control region above and exterior of the ramp region; and
a susceptor attachment second surface adjacent the susceptor plate first surface.

2. The susceptor assembly of claim 1, wherein the susceptor plate comprises at least one of aluminum, nickel alloy, or ceramic.

3. The susceptor assembly of claim 2, further comprising an elevator coupled to the susceptor plate, wherein the elevator is configured to raise and lower the susceptor plate.

4. The susceptor assembly of claim 3, further comprising a controller in electronic communication with the elevator, the controller configured to control the raising and lowering of the elevator.

5. The susceptor assembly of claim 4, wherein the susceptor attachment is a susceptor cap and the susceptor assembly further comprises a susceptor notch disposed within the susceptor plate.

6. The susceptor assembly of claim 5, wherein the susceptor cap comprises a cavity configured to receive the susceptor notch.

7. The susceptor assembly of claim 4, wherein the susceptor attachment is a susceptor ring and wherein the susceptor plate and the susceptor ring are coupled together at a perimeter of the susceptor plate first surface.

8. A reactor system, comprising:
a reaction chamber comprising an upper region and a lower region;
a gas distribution device disposed within the upper region, wherein the gas distribution device comprises a gas distribution device first surface;
a susceptor plate comprising a susceptor plate first surface; and
a susceptor attachment comprising:
a susceptor attachment first surface, the susceptor attachment first surface comprising a ramp region and a conductance control region above and exterior of the ramp region; and
a susceptor attachment second surface adjacent the susceptor plate first surface.

9. The reactor system of claim 8, further comprising an elevator coupled to the susceptor plate for raising and lowering the susceptor plate.

10. The reactor system of claim 9, comprising a controller in electronic communication with the elevator to control the raising and lowering of the susceptor plate.

11. The reactor system of claim 10, comprising a variable gap between the gas distribution device first surface and the conductance control region of the susceptor attachment first surface.

12. The reactor system of claim 11, wherein in a low conductance mode, the controller is configured to control the variable gap between about 0.2 millimeters to about 1.5 millimeters.

13. The reactor system of claim 12, wherein in a high conductance mode, the controller is configured to control the variable gap between about 3.5 millimeters to about 5.5 millimeters.

14. The reactor system of claim 8, wherein the susceptor attachment is a susceptor cap or a susceptor cap, or a combination thereof.

15. A reactor system, comprising:
a reaction chamber comprising an upper region and a lower region;
a gas distribution device disposed within the upper region, wherein the gas distribution device comprises a gas distribution device first surface;
a susceptor plate comprising a susceptor plate first surface;
a susceptor attachment comprising:
a susceptor attachment first surface, the susceptor attachment first surface comprising a ramp region and a conductance control region above and exterior of the ramp region; and
a susceptor attachment second surface adjacent the susceptor plate first surface; and
a chamber sealing assembly in contact with the susceptor attachment, comprising:
a sealing ring comprising a sealing ring first surface;
a member coupled to the sealing ring first surface;
a flange coupled to the member; and
a spring coupled to the flange.

16. The reactor system of claim 15, further comprising a reaction chamber flange disposed between the upper region and the lower region, wherein the spring is coupled to the reaction chamber flange and the flange.

17. The reactor system of claim 16, wherein the sealing ring comprises aluminum, nickel alloy, ceramic or quartz.

18. A method comprising the steps of:
providing a substrate within a reaction chamber of a reactor system, wherein the reactor system comprises:
an upper region and a lower region, wherein the upper region comprises a reaction space;
a gas distribution device disposed within the upper region, wherein the gas distribution device comprises a gas distribution device first surface; and
a susceptor assembly comprising:
a susceptor plate comprising a susceptor plate first surface; and
a susceptor attachment comprising:
a susceptor attachment first surface, the susceptor attachment first surface comprising a ramp region and a conductance control region, and
a susceptor attachment second surface adjacent the susceptor plate first surface, and
an elevator coupled to the susceptor plate, wherein the elevator is configured to raise and lower the susceptor plate; and
manipulating, using the susceptor assembly, a conductance of an exhaust path of the reaction space by moving the conductance control region of the susceptor assembly relative to the gas distribution device first surface.

19. The method of claim 18, wherein the step of manipulating the conductance comprises raising the susceptor plate, with the elevator, so that a variable gap between the gas distribution device first surface and the conductance control region of the susceptor attachment first surface is between about 0.2 millimeters to about 1.5 millimeters.

20. The method of claim 18, wherein the step of manipulating the conductance comprises lowering the susceptor plate, with the elevator, so that a variable gap between the gas distribution device first surface and the conductance control region of the susceptor attachment first surface is between about 3.5 millimeters to about 5.5 millimeters.

21. The method of claim 18, wherein the method comprises one or more deposition cycles, wherein the one or more deposition cycles each comprise:
pulsing a first precursor into the reaction chamber, wherein the first precursor is pulsed into the reaction chamber at a first pressure and a first flow rate,
purging the reaction chamber using a first purge gas, and
pulsing a reactant into the reaction chamber, wherein the reactant is pulsed into the reaction chamber at a second pressure and a second flow rate.
